(19) United States
(12) Patent Application Publication
(10) Pub. No.: US 2009/0153149 A1
(43) Pub. Date: Jun. 18, 2009

(54) OBSTRUCTIONLESS INLINE FLEX FUEL SENSOR

(76) Inventors: Norberto Hernandez, Chihuahua (MX); Jesus Carmona, Chihuahua (MX); Esau Aguinaga, Chihuahua (MX); Manuel S. Sanchez, Chihuahua (MX)

Correspondence Address: DELPHI TECHNOLOGIES, INC., M/C 480-410-202, PO BOX 5052, TROY, MI, 48007, US

(21) Appl. No.: 11/954,824

(22) Filed: Dec. 12, 2007

(51) Int. Cl. G01R 27/26

(52) U.S. Cl. 324/663

(57) ABSTRACT

A sensing apparatus for determining a property of a fuel such as a gasoline and ethanol blend known as flex fuel includes an acetal plastic tube with an inlet, an outlet and a fuel passage in between. One property is a dielectric constant. A pair of semi-circular shaped sensing plates are placed around the tube in concentric relation therewith, leaving the fuel passage unobstructed. A processing circuit on a printed circuit board (PCB) is located near and connected with the sensing plates. The circuit applies an excitation signal, senses a capacitance, and generates an output signal indicative of a property of the fuel. A shield for reducing EMI surrounds and encloses the sensing plates and the PCB. The sensed capacitance will increase with increasing concentration of ethanol in the fuel flowing through the passage. An interface connector allows the sensing apparatus to output the indicative signal to an engine controller.

### TECHNICAL FIELD

The present invention relates generally to sensors and more particularly to a fuel sensor having sensing plates that do not obstruct a fuel passage.

### BACKGROUND OF THE INVENTION

Due to the fact that ethanol is a renewable fuel, and for other reasons as well, the use of ethanol and ethanol blends (i.e., ethanol and gasoline) continues to grow. For example, flexible fuel vehicles are known that are designed to run on gasoline as a fuel or a blend of up to 85% ethanol (E85). Properties of such fuels, such as its conductivity or dielectric constant, can be used to determine the concentration of ethanol in the gasoline/ethanol blend and can also be used to determine the amount of water mixed in with the fuel. Experimental data shows that the fuel dielectric constant is directly proportional to the ethanol concentration but relatively insensitive to water contamination, provided that the water concentration is below about 1% since the dielectric constant of water is around 80 at 25° C. (i.e., surveys show that the water concentration on most U.S. Flex fuel stations is below 1%). On the other hand, fuel conductivity is very sensitive to water concentration. For example, ethanol has a dielectric constant of around 24 at 25 degrees Celsius while gasoline has a dielectric constant of around 2 at the same temperature. Determining the properties of such fuels is important for operation of a motor vehicle since an engine controller or the like can use the information regarding the composition, quality, temperature and other properties of the fuel to adjust air/fuel ratio, ignition timing and injection timing, among other things. Additionally, increasingly strict emissions-compliance requirements have only further strengthened the need for an accurate flexible fuel sensor.

As added background, most sensor technologies for fuel property sensing require in-situ signal processing electronics to convert the relatively small sensing signals to a suitably strong electrical signal that can be used by an external circuit, such as an engine controller, to define the measured fuel property of interest. For example only, a capacitive sensor, which is configured to apply an excitation signal to spaced apart sensing plates, induces a relatively small response signal, thus requiring local electronics to preserve the signal-to-noise ratio.

It is also known that most in-situ sensors (e.g., capacitive, inductive or magnetic technologies) do not require direct contact or exposure to the fuel in order to assess the relevant fuel properties. Nonetheless, these sensors generally benefit from the physical isolation from the fuel, since contact with the fuel can often degrade the performance of the sensor. While it is known to use coatings to isolate various sensor components from contact with the fuel, such coatings may induce stress and/or degrade the signal-to-noise ratio of the sensing approach.

Fuel passage obstruction is another shortcoming of conventional fuel sensors, particularly capacitance-based approaches. More specifically, to measure the capacitance of the fuel, conventional sensors are known to use plates with different shapes, but in all such applications these plates are inside the fuel line (i.e., the fuel passage). This makes the construction of such sensors more complex and poses a potential for obstructing the fuel flow. Additionally, this approach imposes stricter requirements to protect the plates from corrosion by the ethanol, as described above.

There is therefore a need for a fuel sensor that minimizes or eliminates one or more of the problems set forth above.

### SUMMARY OF THE INVENTION

The invention is directed to a fuel sensing apparatus where the sensing plates are placed outside the fuel passage so that no obstruction to fuel flow is produced. Additionally, the sensing plates and signal processing electronics are located away from any contact with the fuel, reducing the risk of degradation due to corrosion, without the use of any coatings or the like, which simplifies the design.

An apparatus is provided for use in sensing one or more properties of a fuel. The apparatus includes a tube and first and second sensing plates. The tube extends along a longitudinal axis and has a hollow interior defining a fuel passage between a fuel inlet and a fuel outlet of the tube. The sensing plates are disposed radially outwardly of the tube on its outer surface tube, leaving the fuel passage unobstructed between inlet and outlet, and also isolating the plates from contact with the fuel. The tube and the sensing plates are preferably in a concentric relationship, with the tube preferably comprising acetal thermoplastic material.

In a preferred embodiment, the sensing plates include a plurality of apertures configured to cooperate with a corresponding plurality of protuberances projecting from the tube to align and retain the sensing plates to the tube. A pair of spacer wheels, enlarged in diameter relative to the tube, extend radially outwardly from the tube at axially opposing ends. A generally cylindrical, hollow shield is located radially outwardly of the tube and is sized to engage and fit on the spacer wheels, where the shield and the spacer wheels cooperate to form a cavity. The cavity encloses the sensing plates and is configured in size and shape so as to be able to house a processing circuit on a printed circuit board (PCB). The processing circuit is therefore located near to and is electrically coupled with the sensing plates and is arranged to determine a characteristic (e.g., a capacitance) of the structure between the plates, which is mainly, in a preferred embodiment, determined by the concentration of ethanol in the fuel flowing through the passage. The processing circuit is configured to generate an output signal indicative of one or properties of the fuel (e.g., dielectric constant).

Other features, aspects and advantages are presented.

### BRIEF DESCRIPTION OF THE DRAWINGS

The present invention will now be described by way of example, with reference to the accompanying drawings:

FIG. 1 is a top, perspective view of an embodiment of an obstructionless inline flexible fuel sensing apparatus according to the invention.

FIG. 2 is an exploded view of the fuel sensing apparatus of FIG. 1.

FIG. 3 is a perspective of a tube portion of the fuel sensing apparatus of FIG. 1 as viewed in the direction of line 3-3 in FIG. 2.

FIG. 4 is a perspective view of a connector portion of the fuel sensing apparatus of FIG. 2.

FIG. 5 is a cross-sectional view of a concentric tube and sensing plate assembly taken substantially along line 5-5 in FIG. 2.

FIG. 6 is a simplified schematic diagram showing the fixed and variable capacitive contributions provided by the tube, and variable ethanol concentration fuel, respectively.

FIG. 7 is a diagram showing how the capacitance of a fuel flowing through the fuel sensing apparatus of FIG. 1 varies with ethanol concentration.

### DETAILED DESCRIPTION OF THE PREFERRED EMBODIMENT

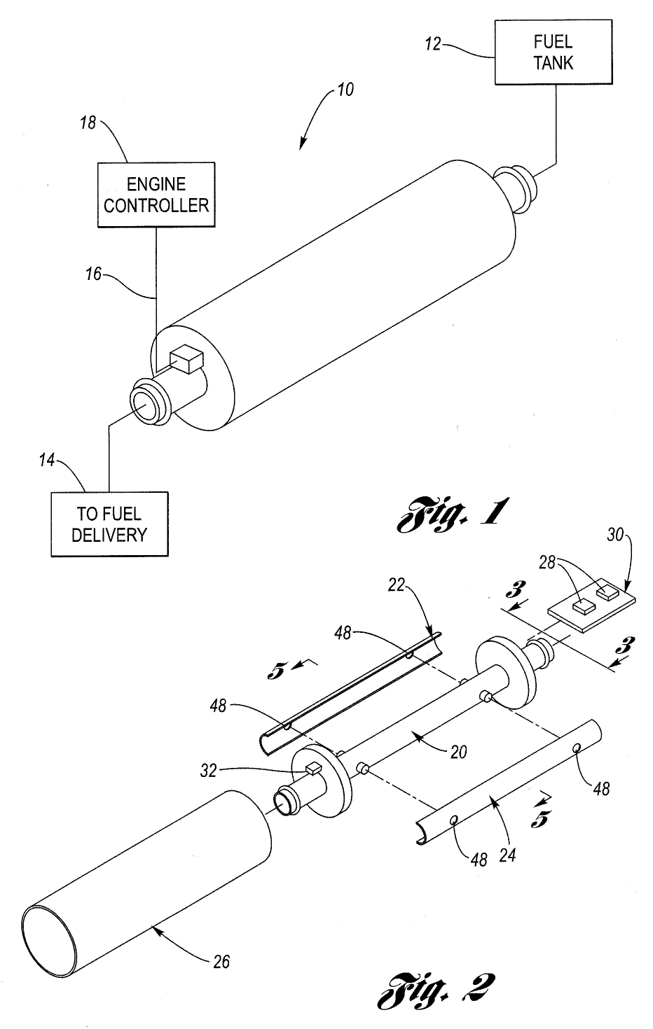

Referring now to the drawings wherein like reference numerals are used to identify identical components in the various views, FIG. 1 is a perspective view of an apparatus 10 for sensing one or more properties of a fuel, such as a dielectric constant of a gasoline/ethanol blend. The sensing apparatus 10, as shown, is an in-line type fuel sensing apparatus that is coupled between a source of fuel, such as a fuel tank 12, and a destination, such as various fuel delivery apparatus 14 associated with an automotive vehicle internal combustion engine (not shown). The sensing apparatus 10, generally, includes a pair of sensing plates surrounding an inner tube, in a concentric manner, which are connected to a closely-located electrical circuit with signal processing capability so as to generate an output signal 16. The sensing plates around the inner tube will form a capacitor. The material between the plates includes a fixed portion, namely the tube walls, which have a fixed dielectric constant. However, the dielectric constant of the fuel flowing through the fuel line will vary, depending on the composition of the fuel itself. The total effective capacitance will be mainly driven by the variable portion. The circuit will measure the capacitance for purposes of generating the signal 16. The output signal 16 is indicative of one or more sensed physical properties of the fuel, such as dielectric constant or conductivity. The output signal 16 may then be provided to, for example only, an electronic engine controller 18 or the like for use in, as known in the art, and as described in the Background, fuel delivery control.

FIG. 2 is an exploded view showing in greater detail the sensing apparatus 10 and its constituent parts described generally above. The sensing apparatus 10 includes a tube 20, a first sensing plate 22, a second sensing plate 24, a shield 26, an electrical processing circuit 28 on a printed circuit board (PCB) 30 and an electrical connector 32. The stack-up assembly, as will be described, is generally concentric, starting with the tube 20 as the innermost component, then the plates 22, 24, and then the shield 26.

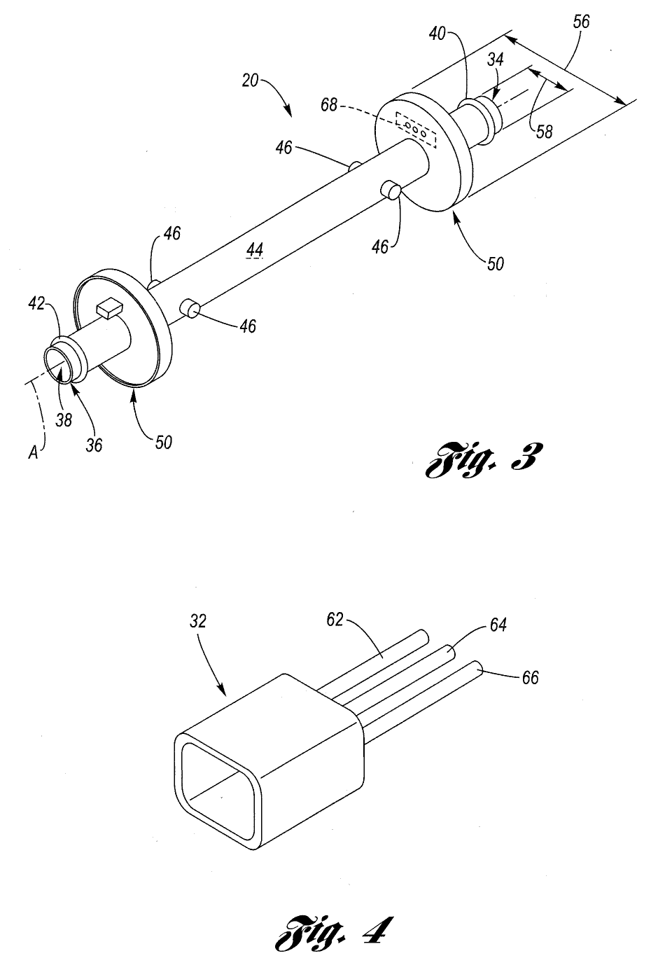

FIG. 3 is an enlarged perspective view showing the tube 20 in greater detail. The tube 20 extends along a main, longitudinal axis labeled “A”. The tube 20 is preferably unitary (i.e., one piece) in construction, solid and continuous, and comprises plastic or other material that is resistant to degradation in the presence of various fuels including gasoline/ethanol blends. In one embodiment, the tube 20 is formed using an engineering plastic, such as a thermoplastic material known as acetal (or sometimes polyacetal). Acetal material exhibits desired chemical resistance properties with respect to the fuel that is contemplated to flow through the sensing apparatus 10.

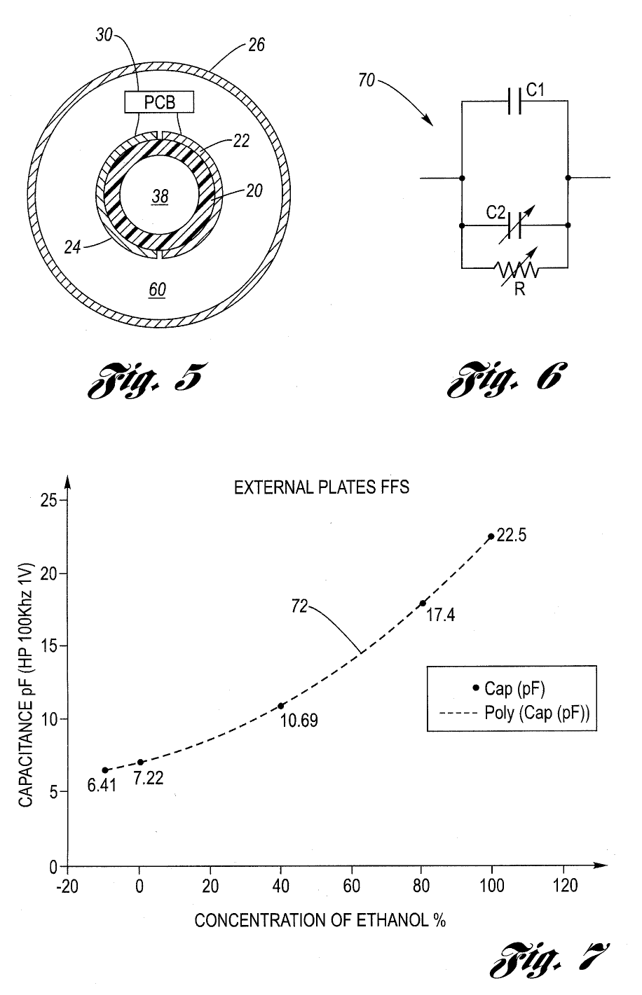

As shown, the tube 20 includes an inlet 34, an outlet 36 and a fuel passage 38 (also shown in FIG. 5) formed in between. It should be appreciated that the inlet and outlet designations here are arbitrary, the principal of operation being applicable to fuel flows in either direction through the fuel passage 38. The inlet 34 and the outlet 36 each include a respective interface that is suitable for connection to a fuel hose or tube or other mechanism, as per the requirements of any particular application. For example only, as illustrated, the inlet 34 and the outlet 36 each include respective O-ring seals 40, 42. Of course, other variations are possible. Significantly, the fuel passage 38 is unobstructed between the inlet 34 and the outlet 36. The sensing plates 22 and 24 are located outside of the tube 20 and hence out of the fuel passage 38, which is unlike the construction of conventional fuel sensors.

The tube 20 further includes an outer surface 44 spaced from the fuel passage 38 (i.e., by the wall thickness of the tube). The tube 20 is substantially circular in radial cross-section (best shown in FIG. 5). The tube 20 also includes a plurality of protuberances 46 configured to cooperate with a corresponding plurality of apertures 48 (FIG. 2) in the sensing plates 22 and 24 configured to align and retain the sensing plates 22, 24 with respect to the tube 20. The protuberances 46 may be snaps or heat stakes, or other conventional approaches for forming projections.

The tube 20 also includes a pair of spacer wheels 50 disposed on axially opposing ends 52 and 54 of the tube 20. Each spacer wheel 50 has a first outside diameter 56 that is larger than an outside diameter 58 of the tube 20. The spacer wheels 50 generally are configured to accommodate the shield 26 and form a fully enclosed sensing apparatus 10. It is preferred that the tube 20 as inclusive of the spacer wheels 50 be unitary (one-piece molded). The spacer wheels 50 may be formed with a radially-outermost sleeve, which if an outer edge is crimped, may be useful to hold the shield 26 in place.

Referring again to FIG. 2, the sensing plates 22 and 24 are generally semi-circular in shape and sized so as to snugly fit radially outwardly directly on the tube 20. The sensing plates 22 and 24 are preferably formed of an electrically-conductive material to which a copper wire or other conductor can be electrically-connected to (e.g., soldered), such as various thin plated metals and alloys known in the art for constructing sensing plates. For example, typical embodiments of the present invention may use a copper-based alloy (e.g., brass) for the sensing plates. The apertures 48 in the plates 22, 24 sized and located in correspondence with protuberances 46 so as to facilitate assembly of the plates to the tube 20. Upon assembly, the sensing plates 22 and 24 engage the outer surface 44 of the tube 20 wherein the sensing plates 22 and 24 and the tube 20 are in a concentric relationship with each other. This is best shown in FIG. 5.

The shield 26 is configured to reduce electromagnetic interference (EMI). More specifically, one function performed by the shield 26 is to minimize or eliminate the effect that stray or external electromagnetic interference may otherwise have on the sensing plates 22 and 24. A second function performed by the shield 26 is to minimize or eliminate any electromagnetic emissions produced by the excitation of the sensing plates 22 and 24 from propagating outwards from the sensing apparatus 10. As to construction, the shield 26 may comprise electrically-conductive material such as various metals and be coupled to a ground terminal of the interface connector 32, either directly via internal conductors or indirectly via a connection on the PCB 30. In the illustrated embodiment, the shield 26 is generally disposed radially outwardly of the tube 20, circumferentially continuous, and has an axial length sufficient to span the spacer wheels 50. The shield 26 is hollow and has an interior surface configured to engage and fit on the outside diameter of the spacer wheels 50. The shield 26 and the spacer wheels 50 cooperate to enclose the sensing plates 22 and 24. In addition, the shield 26 and the spacer wheels 50 cooperate to form a closed cavity 60 (i.e., the radially-outwardly extending space between the sensing plates/tube, on the one hand, and the interior surface of the shield 26, on the other hand.

FIG. 5 is a cross-sectional view of the sensing apparatus 10 taken substantially along line 5-5 in FIG. 2. As shown, the circuit 28 on the PCB 30 is electrically coupled to the sensing plates 22 and 24. Such a connection may be made using, conventionally, either separate wires or through suitably configured extensions of the sensing plates themselves that would terminate directly on the PCB. The PCB 30 is preferably located close to the sensing plates 22 and 24, and in the preferred embodiment, the PCB 30 is disposed within the cavity 60 of the sensing apparatus 10. The cavity 60 is thus configured in size and shape to at least house the printed circuit board (PCB) 30. While this will be described in greater detail below, generally, to perform its function, the signal processing circuit 28 is configured to apply suitable excitation signals to the sensing plates 22 and 24 and to detect and process the resulting induced signals to develop the output signal 16 indicative of a physical property of the fuel. The close proximity of the circuit 28 to the sensing plates improves the signal-to-noise ratio of the detected induced signal.

Referring to FIGS. 2 and 4, the interface connector 32 may comprise conventional construction approaches and materials, and may include a plurality of electrical terminals. In one embodiment, the connector 32 may include power, ground and output signal electrical terminals designated by reference numerals 62, 64 and 66, respectively (FIG. 4). Leads from these terminals 62, 64 and 66 are electrically connected to the circuit 28 on the PCB 30. In the embodiment where the PCB 30 is situated in the cavity 60, the leads 62, 64 and 66 from the connector 32 may pass through a series of axially-extending apertures 68 located in a main wall of one of the spacer wheels 50, as shown in FIG. 3 enclosed in a dashed-line box. The leads may then be connected to the PCB 30 using conventional means (e.g., soldering).

FIG. 6 is a simplified schematic diagram showing a simplified equivalent circuit 70 representing the sensing apparatus 10. It should be understood that in the present disclosure, a pair of sensing plates 22 and 24, with fuel flowing in the fuel passage 38, will appear to the electronics on PCB 30 as a complex load (e.g., a parallel combination of a resistor and a capacitor). More specifically, the tube 20 and the two sensing plates form a relatively small value capacitor, which is designated C1 in FIG. 5. Generally speaking, the value of C1 is fixed. When fuel flows through the fuel passage 38, an additional capacitance is added to the complex load, which is variable and depends on the particular properties of the fuel. This variable capacitance is designated C2 in FIG. 5. As described, the greater the ethanol concentration, the greater is the composite dielectric constant of the fuel blend. Since capacitance is determined based generally on plate geometry, spacing (which are fixed), and the dielectric constant of the material between the plates (which may vary here), it can be seen that the sensed capacitance C2 increases with higher concentrations of ethanol in a gasoline/ethanol blend. There is an additional resistive component, which is also variable, and is designated R in FIG. 5. This complex impedance comprises a real component part (resistive) and an imaginary component part (capacitive), which can be deconstructed and correlated to a conductivity and a dielectric constant, useful physical properties of the fuel. In particular, a dielectric constant can be derived from sensed capacitance using known relationships. The art is replete with approaches for measuring the complex impedance, or components thereof, for purposes of ascertaining one or more physical properties of the fuel, for example, as seen by reference to U.S. application Ser. No. 10/199,651 filed Jul. 19, 2002, now U.S. Pat. No. 6,693,444 B2 entitled “CIRCUIT DESIGN FOR LIQUID PROPERTY SENSOR” issued Feb. 17, 2004 to Lin et al., owned by the common assignee of the present invention, and hereby incorporated by reference in its entirety herein.

FIG. 7 is a chart showing the increase in sensed capacitance with increasing concentrations of ethanol in a gasoline/ethanol blend (e.g., a Flex Fuel). As shown, trace 72 represents a curve-fit relationship between particular measured plotted points. It should be understood that suitable a configuration of the signal processing circuit 28 may be employed to obtain a desired relationship of the output signal 16 and the variable concentration fuel. Alternatively, the controller 18 may be suitably configured to process a raw signal 16 to obtain or extract the desired information of the fuel properties.

While the invention has been described in connection with what is presently considered to be the most practical and preferred embodiment, it is to be understood that the invention is not to be limited to the disclosed embodiments but, on the contrary, is intended to cover various modifications and equivalent arrangements included within the spirit and scope of the appended claims, which scope is to be accorded the broadest interpretation so as to encompass all such modifications and equivalent structures as is permitted under the law.

1. An apparatus for use in sensing one or more properties of a fuel, comprising:
a tube extending along a longitudinal axis, said tube having a hollow interior defining a fuel passage between a fuel inlet and a fuel outlet; and
first and second sensing plates being disposed radially outwardly of said tube on an outer surface thereof so as to leave said fuel passage unobstructed.

2. The apparatus of claim 1 wherein said body comprises electrically-insulating thermoplastic material.

3. The apparatus of claim 2 wherein said thermoplastic material comprises acetal material.

4. The apparatus of claim 1 wherein said sensing plates comprise electrically-conductive material.

5. The apparatus of claim 4 wherein said tube is substantially circular in radial cross-section, said sensing plates comprising electrically-conductive material and being semi-circular in shape, said sensing plates and said tube being in concentric relation.

6. The apparatus of claim 5 wherein said tube comprising a plurality of protuberances configured to cooperate with a corresponding plurality of apertures in said sensing plates configured to align and retain said sensing plates to said tube.

7. The apparatus of claim 5 further including a pair of spacer wheels disposed on axially opposing ends of said tube, a first outside diameter of said spacer wheels being larger than a second outside diameter of said tube.

8. The apparatus of claim 7 further including a shield radially outwardly of said tube, said shield being hollow and having an interior surface configured to engage and fit on said spacer wheels, said shield and spacer wheels cooperating to enclose said sensing plates and form a closed cavity.

9. The apparatus of claim 8 wherein said shield comprises electrically-conductive material configured to reduce electromagnetic interference (EMI).

10. The apparatus of claim 9 wherein said shield is grounded.

11. The apparatus of claim 8 further including an electrical circuit configured on a printed circuit board (PCB), said circuit being electrically coupled to said sensing plates and generally an output signal indicative of the one or more properties of said fuel.

12. The apparatus of claim 1 wherein said PCB is located in said closed cavity.

13. The apparatus of claim 12 wherein one of said properties comprises a dielectric constant of the fuel flowing through said fuel passage.

14. The apparatus of claim 1 further including a connector comprising electrical terminals.

15. An fuel sensor comprising:
a tube comprising thermoplastic material extending along a longitudinal axis, said tube having a hollow interior defining a fuel passage between a fuel inlet and a fuel outlet, said tube being substantially circular in radial cross-section;
a plurality of protuberances projecting from said tube;
first and second sensing plates disposed radially outwardly of said tube on an outer surface thereof so as to leave said fuel passage unobstructed, said sensing plates including a plurality of apertures configured to cooperate with said protuberances to align and retain said sensing plates to said tube, said plates being semi-circular in shape, said plates and said tube being in concentric relation;
a pair of spacer wheels disposed on axially opposing ends of said tube, a first outside diameter of said spacer wheels being larger than a second outside diameter of said tube;
a shield radially outwardly of said tube, said shield being hollow and having an interior surface configured to engage and fit on said spacer wheels, said shield and said spacer wheels cooperating to form a cavity enclosing said sensing plates; and
an electrical circuit on a printed circuit board (PCB) disposed in said cavity, said circuit being electrically coupled to said sensing plates and configured to generate an output signal indicative of one or more properties of said fuel; and
an interface connector comprising an electrical terminal coupled to said circuit for receiving said output signal.

16. The apparatus of claim 15 wherein said circuit is configured to excite said sensing elements and detect the resulting induced signals, wherein one of said properties is a dielectric constant.

17. The apparatus of claim 15 wherein said thermoplastic material comprises acetal material.
